(19) United States
(12) Patent Application Publication
(10) Pub. No.: US 2012/0313428 A1
(43) Pub. Date: Dec. 13, 2012

(54) COMMUNICATION SYSTEM AND ELECTRONIC CHOKE CIRCUIT

(75) Inventor: Kenji Kuniyoshi, Osaka (JP)

(73) Assignee: PANASONIC CORPORATION, Osaka (JP)

(21) Appl. No.: 13/577,702

(22) PCT Filed: Jul. 21, 2010
(86) PCT No.: PCT/JP2010/062199

§ 371 Date: Aug. 8, 2012

(30) Foreign Application Priority Data
Feb. 16, 2010 (JP) 2010-031576

(51) Int. Cl. H04B 3/54; H03H 7/01

(52) U.S. Cl. 307/3; 333/176

(57) ABSTRACT

The object of the invention is to propose a communication system using an electronic choke circuit which has impedance slightly varied with a load variation and is prevented from having negative resistance and can stabilize circuit operation. A terminal device includes an electronic choke circuit separating DC power supplied from a management device and a communication signal from each other. The electronic choke circuit includes a variable impedance element constituted by a transistor having its collector and its emitter respectively connected to a first terminal and a third terminal, and an inductor and a resistor connected in series with the variable impedance element. A series circuit of a first resistor and a first capacitor is interposed between the first terminal and a second terminal, and the first capacitor has its one end connected to a base of the variable impedance element. A second capacitor is interposed between the third terminal and a fourth terminal. A second resistor suppresses a phenomenon that resistance characteristics of a circuit between an input terminal and an output terminal have a negative resistance region within a frequency band including a frequency of the communication signal.

### TECHNICAL FIELD

The present invention relates to a communication system designed to transmit electric power and a communication signal via the same transmission line, and an electronic choke circuit used for separation of a communication signal and electric power in this communication system.

### BACKGROUND ART

In the past, with regard to a communication device establishing wired communication, there have been proposed techniques of using the transmission line as a communication line and a power line in order to perform communication and power supply via the same transmission line. As this kind of techniques, there have been proposed a power line communication technique of additionally using a line primarily intended to supply power for transmission of a communication signal, and a technique of enabling a communication device to obtain electrical power of a communication signal via a line primarily intended to transmit a communication signal.

In such a technique of using a transmission line for communication and power supply, it is necessary for a communication device to involve a circuit designed to separate a communication signal and electric power from each other. In many cases, such a circuit designed to separate the communication signal and the electric power from each other utilizes a difference between frequency bands of the communication signal and the electric power for separation of the communication signal and the electric power. More specifically, the separation of the communication signal and the electric power is achieved by use of a low-pass filter or an electric choke circuit having high impedance to the communication signal and low impedance to the electric power.

For example, JP 2000-341181 A (hereinafter referred to as “document 1”) discloses a technique of using a low-pass filter for separating a DC voltage applied to a transmission line (e.g., a telephone line) and a communication signal in the form of an AC from each other in a communication device (e.g., a phone and a modem for telephone lines). The low-pass filter is interposed between the transmission line and a voltage regulator for supplying power to an internal circuit of the communication device.

This low-pass filter is designed as a balanced circuit, and includes two transistors, two resistors respectively connected between collectors and bases of the respective transistors, and a capacitor interposed between the bases of the respective transistors. Each of the transistors has its collector-emitter part interposed between the transmission line and the voltage regulator.

According to this configuration, since the communication signal of an AC can flow through the capacitor, the transistor acts as a high impedance element for the communication signal. Further, since a DC cannot flow through the capacitor, the transistor acts as a low impedance element for the DC. Consequently, the low-pass filter can separate the DC power and the communication signal from each other.

The low-pass filter with this configuration has a function similar to an inductor (choke coil), and therefore can be considered as an electric choke circuit. Further, the low-pass filter can be smaller and lighter than the inductor having the substantially same separation performance of the communication signal as the low-pass filter, yet the low-pass filter with this configuration has a similar function to the inductor.

With regard to the low-pass filter disclosed in document 1, it is necessary to increase the input impedance of the voltage regulator in order to increase the input-side impedance of the low-pass filter for the purpose of improving the separation performance of the communication signal. That is because the input-side impedance is limited by the characteristics of the transistor and the resistor connected between the collector and the base of the transistor. Consequently, with respect to the low-pass filter with this configuration, it is impossible to connect a capacitor to the input side of the voltage regulator for the purpose of reducing noise, for example.

Further, in the configuration disclosed in document 1, the transistor has its base grounded via the capacitor. Thus, even if the load resistance including a resistance of the voltage regulator is varied, the input-side impedance of the low-pass filter sees slight influence. However, the input-side impedance is limited by the resistance of the resistor connected between the collector and the base of the transistor. Therefore, it is difficult to use the above configuration for application requiring higher impedance.

For the purpose of increasing the impedance, it is considered that an inductor is interposed between the emitter of the transistor and a DC load. However, when a capacitor is connected to the input-side of the voltage regulator and the above inductor is provided, resonance of the capacitor and the inductor is likely to occur. Such resonance may cause a frequency band within which a phase angle (hereinafter merely referred to as “phase”) between two terminals of an input terminal of the low-pass filter is equal to or more than 90 degree. Within the frequency band where the phase is equal to or more than 90 degree, the low-pass filter may have negative resistance that the impedance has a negative real part. Consequently, such negative resistance may cause a vibration and an oscillation of the electrical circuit network.

### DISCLOSURE OF INVENTION

The object of the present invention is to propose an electric choke circuit capable of increasing the impedance without using a large-size inductor as well as stabilizing a circuit operation by reducing a change in the impedance caused by a load variation and preventing a negative resistance phenomenon. Further, the other object of the present invention is to propose a communication system capable of improving performance of separating a communication signal and electric power from each other by use of the electric choke circuit.

For the purpose of achieving the above object, the communication system in accordance with the present invention includes: a management device and a terminal device designed to communicate with each other via a transmission line; and a power supply unit configured to supply electric power to the terminal device via the transmission line. The terminal device includes: an electronic choke circuit configured to separate the electric power supplied from the power supply unit and a communication signal from each other; and a power receiving unit configured to receive the electric power separated from the communication signal by the electronic choke circuit. The electric choke circuit includes: a first terminal and a second terminal constituting an input terminal adapted in use to be connected the transmission line; a third terminal and a fourth terminal constituting an output terminal adapted in use to be connected the power receiving unit; a variable impedance element placed in at least one of a position between the first terminal and the third terminal and a position between the second terminal and the fourth terminal, the variable impedance element being configured to vary its impedance in accordance with a voltage applied to a control terminal; an inductor interposed between the variable impedance element and the output terminal; a first capacitor connected between the first terminal and the second terminal via a first resistor so as to apply its terminal voltage to the control terminal of the variable impedance element; a second capacitor interposed between the third terminal and the fourth terminal; and a second resistor connected between the variable impedance element and the output terminal, the second resistor configured to suppress a phenomenon that resistance characteristics of a circuit between the input terminal and the output terminal have a negative resistance region within a frequency band including at least a frequency of the communication signal.

Preferably, the electronic choke circuit further includes a third resistor connected in series with the first resistor. Connected in parallel with the variable impedance element is a series circuit of the first resistor and the third resistor.

Preferably, the electronic choke circuit is designed as a balanced circuit.

Preferably, the communication system includes a plurality of the terminal devices connected to the transmission line.

For the purpose of achieving the above object, the electric choke circuit in accordance with the present invention includes: a first terminal and a second terminal constituting an input terminal; a third terminal and a fourth terminal constituting an output terminal; a variable impedance element placed in at least one of a position between the first terminal and the third terminal and a position between the second terminal and the fourth terminal, the variable impedance element being configured to change its impedance in accordance with a voltage applied to a control terminal; an inductor interposed between the variable impedance element and the output terminal; a first capacitor connected between the first terminal and the second terminal via a first resistor so as to apply its terminal voltage to the control terminal of the variable impedance element; a second capacitor interposed between the third terminal and the fourth terminal; and a second resistor connected between the variable impedance element and the output terminal, the second resistor configured to suppress a phenomenon that resistance characteristics of a circuit between the input terminal and the output terminal have a negative resistance region within a frequency band including at least a frequency of the communication signal.

### BRIEF DESCRIPTION OF DRAWINGS

FIG. 1 is a circuit diagram illustrating the first embodiment,

FIG. 2 is a characteristic diagram of the electronic choke circuit used in the above embodiment,

FIG. 3 is a circuit diagram illustrating the second embodiment,

FIG. 4 is a characteristic diagram of the electronic choke circuit used in the above embodiment,

FIG. 5 is a circuit diagram illustrating the third embodiment,

FIG. 6 is a circuit diagram illustrating the fourth embodiment,

FIG. 7 is a characteristic diagram of the electronic choke circuit used in the above embodiment,

FIG. 8 is a block diagram illustrating a usage example, and

FIG. 9 is a block diagram illustrating a primary part of the usage example.

### BEST MODE FOR CARRYING OUT THE INVENTION

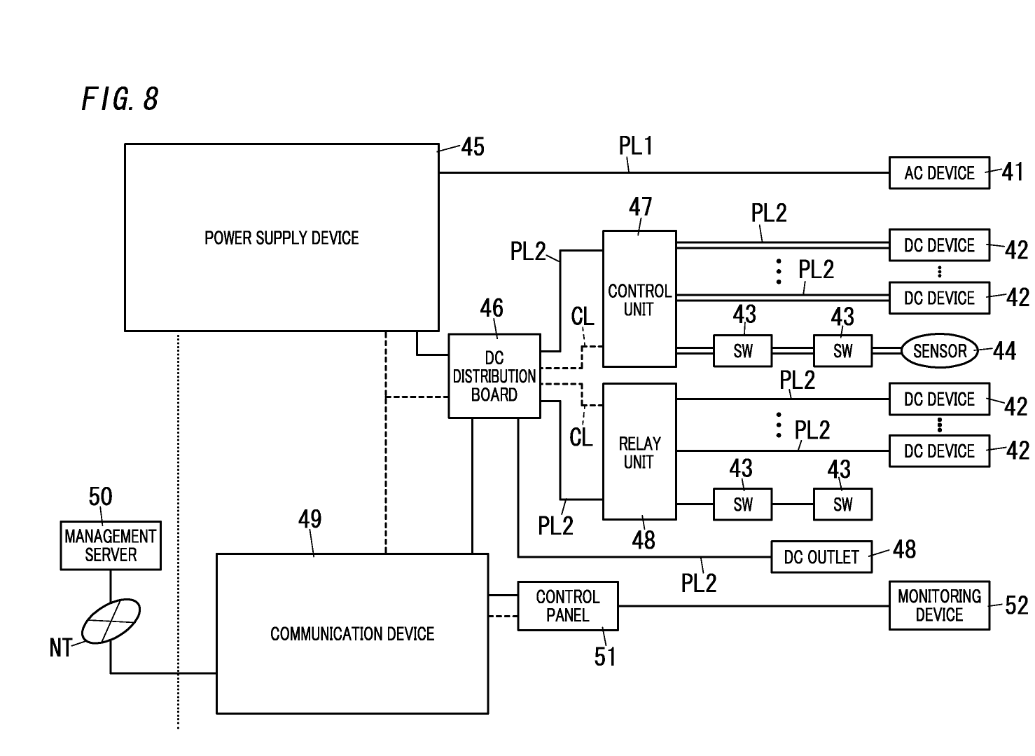

A configuration instance illustrated in FIG. 8 is used for promotion of understanding of the present invention, but the application of the embodiments to be described is not limited to the instance shown in FIG. 8. FIG. 8 illustrates a residential power distribution system employing wire communication for monitoring and controlling various devices placed in a residence.

For example, the devices include an AC device 41 designed to operate with AC power, a DC device 42 designed to operate with DC power, a switch 43 for controlling the AC device 41 and/or the DC device 42, a sensor 44 for measuring an amount indicative of environment (e.g., luminance and temperature). The sensor 44 may be a sensor used for prevention of disaster (e.g., fire and gas leakage) or crime (e.g., intrusion and window-smashing).

It is sufficient that a power supply device 45 illustrated is a power source (e.g., a commercial power source, a solar power generation device, a fuel cell, and a storage cell) configured to supply power to a residence. Notably, the illustrated power supply device 45 has a function of outputting AC power to an AC transmission line PL1 and a function of outputting DC power to a DC transmission line PL2.

Further, the residential power distribution system illustrated includes a DC distribution board 46 designed to distribute DC power. The DC distribution board 46 distributes DC power received from the power supply device 45 into multiple systems serving as the DC transmission lines PL2. Moreover, the DC distribution board 46 is connected to a control unit 47 and a relay unit 48 via the branched DC transmission lines PL2.

The relay unit 48 is configured to turn on a relay incorporated therein so as to supply power to the connected DC device 42 and to turn off the relay to terminate supplying power to the connected DC device 42. The control unit 47 has a function of providing operation instruction to the DC device 42. Consequently, the control unit 47 is capable of controlling turning on and off the DC device 42, and further is capable of selecting operation (e.g., operation mode) of the DC device 42 and adjusting a condition (e.g., brightness and temperature) of the DC device 42.

Each of the control unit 47 and the relay unit 48 is connected to at least one of the switch 43 and the sensor 44, and monitors the corresponding switch 43 and/or sensor 44 by use of a communication technique, and controls the DC device 42 in accordance with the obtained condition. The control unit 47 and the relay unit 48 can communicate with the DC distribution board 8 via a communication line CL, in addition to the switch 43 and/or sensor 44. Consequently, the control unit 47 and the relay unit 48 can control the operation of the DC device 42 in accordance with the instruction received from the DC distribution board 8.

Further, the DC distribution board 46 is connected, via the DC transmission line PL2, to a DC outlet 48 provided to the residence as a wall outlet or a floor outlet. Connecting a plug of a DC device (not shown) to the DC outlet 48 enables supplying DC power to the DC device.

The DC distribution board 46 can communicate with a communication device 49 via the communication line CL. The DC distribution board 46 supplies DC power to the communication device 49 via the DC transmission line PL2. The communication device 49 includes a home server having a function of communicating with a device placed in the residence to monitor and control the device. The home server obtains information measured by a power meter, and has a function of communicating with an outside management server 50 (e.g., a server of an electric power company) via a wide area network (e.g., an Internet) NT.

Information obtained by the communication device 49 including the home server can be monitored by use of a control panel 51 including a display unit for displaying an image and a manipulation unit for inputting various instructions. Further, it is possible to send an instruction regarding the control of the DC device 42 by use of the control panel 51. Moreover, the control panel 51 can communicate with a monitoring device 52 such as a door-phone slave and a monitoring camera, and also functions as a door-phone master or a display device for a monitored image.

Besides, telecommunication among the DC device 42, the switch 43, the sensor 44, and the control unit 47 is established based on a communication technique using power line carrier communication. In brief, the DC transmission line PL2 among the DC device 42, the switch 43, the sensor 44, and the control unit 47 is used for transmitting DC power and is further used as a communication line for transmitting a communication signal based on a high frequency carrier superimposed on a DC voltage.

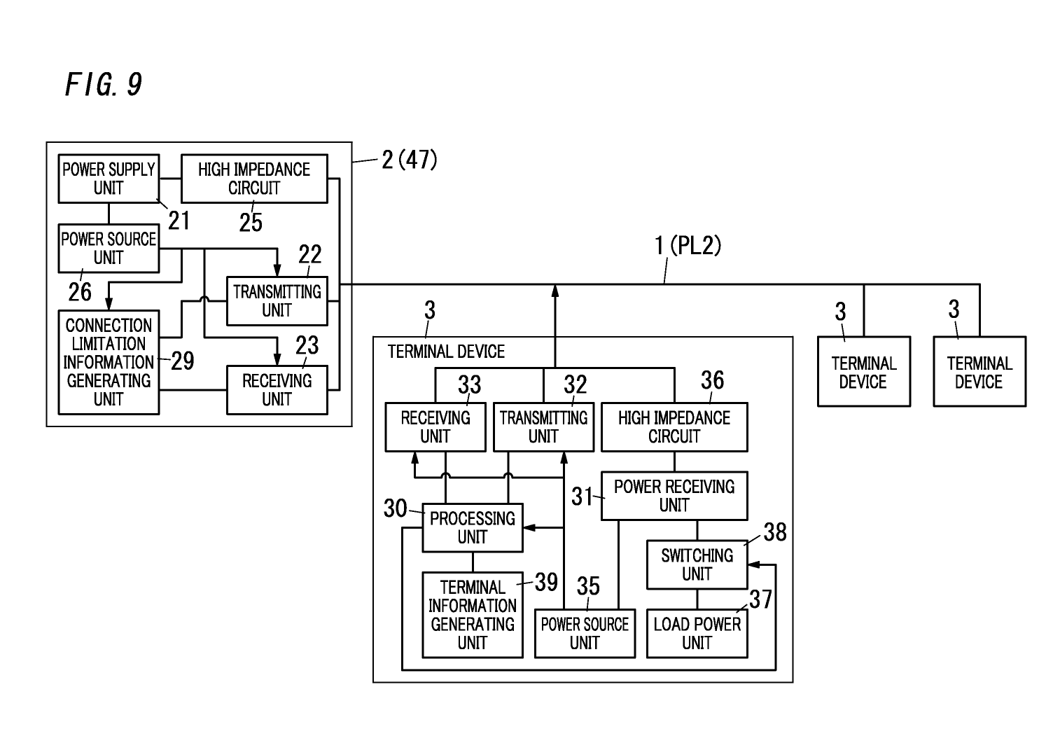

In the following explanation, the DC device 42, the switch 43, and the sensor 44 are considered as terminal devices 3 of a communication system. The explanation is made to the communication system in which the terminal devices 3 are connected to the control unit 47 serving as a management device 2 via the DC transmission line PL2 serving as a transmission line 1. In brief, as shown in FIG. 9, a relation among the DC device 42, the switch 43, the sensor 44, and the control unit 47 can be described as a relation between the management device 3 and the terminal device 3.

The management device 2 illustrated includes a power supply unit 21 containing the power supply device 45 and the DC distribution board 46 as illustrated in FIG. 8 and configured to receive electric power from the outside and output a DC constant voltage. The power supply unit 21 is configured to output DC power to the transmission line 1 via a high impedance circuit 25. In brief, the power supply unit 21 has a function of supplying DC power to the terminal device 3. The high impedance circuit 25 is designed to have relatively high impedance to a communication signal from the transmission line 1 and to have relatively low impedance to DC power.

Further, the management device 2 includes a transmitting unit 22 for transmission of a communication signal and a receiving unit 23 for receipt of a communication signal. The transmitting unit 22 and the receiving unit 23 are connected to the transmission line 1. Consequently, the DC voltage outputted from the high impedance circuit 25 is applied to the transmission line 1, and the communication signal with a high frequency transmitted by the transmitting unit 22 and received by the receiving unit 23 is superimposed on the DC voltage.

Moreover, the management device 2 includes a connection limitation information generating unit 29 configured to limit the connection of the terminal 3 on the basis of supplied power from the power supply unit 21 and consumed power by the terminal device 3. The transmitting unit 22 and the receiving unit 23 create a communication signal based on connection limitation information generated by the connection limitation information generating unit 29. In addition, the management device 2 includes a power source unit 26 for receiving power from the power supply unit 21 and then supplying power to the transmitting unit 22, the receiving unit 23, and the connection limitation information generating unit 29.

Meanwhile, each terminal 3 includes a power receiving unit 3 configured to receive, via a high impedance circuit 36, DC power supplied through the transmission line 1. The high impedance circuit 36 is designed to have high impedance to a communication signal from the transmission line 1 and to have low impedance to DC power. The high impedance circuit 36 therefore separates, from a communication signal, DC power supplied from the transmission line 1 and provides the separated DC power to the power receiving unit 31.

The terminal device 3 includes a transmitting unit 32 for transmission of a communication signal and a receiving unit 33 for receipt of a communication signal. Further, the terminal device 3 includes a processing unit 30 configured to process information transmitted by the transmitting unit 32 by use of a communication signal and to process information received by the receiving unit 33 by use of a communication signal.

Inputted into the processing unit 30 is terminal information regarding operation of a terminal from a terminal information generating unit 39. For example, the terminal information includes a class of the terminal device 3 serving as a load consuming DC power, consumption power predicted when the terminal device 3 starts to consume DC power, and operation condition of the terminal device 3 serving as a load while it consumes DC power. The processing unit 30 inputs the terminal information from the terminal information generating unit 39 into the transmitting unit 32, thereby transmitting a communication signal including the terminal information to the management device 2.

The terminal device 3 has a function of acting as a load consuming DC power, and such a function is implemented by a load power unit 37 in FIG. 9. Interposed between the power receiving unit 31 and the load power unit 37 is a switching unit 38. The processing unit 30 provides an instruction to the switching unit 38 to control power supply from the power receiving unit 31 to the load power unit 37. The switching unit 38 basically controls power supplied to the load power unit 37 to turn on and off the load power unit 37. The switching unit 38 is configured not to supply power from the power receiving unit 31 to the load power unit 37 unless the terminal device 3 announces the start of consumption of DC power to the management device 2 and in response to the announcement the management device 2 allows the operation of the terminal device 3.

Besides, with regard to the terminal device 3, power supply to the processing unit 30, the transmitting unit 32, and the receiving unit 33 is performed by the power source unit 35 configured to receive power from the power receiving unit 31 and then output a DC voltage. The power source unit 35 supplies power regardless of the condition of the load power unit 37.

According to the above configuration, prior to consumption of DC power by the terminal device 3, the terminal device 3 announces the terminal information to the management device. Thus, the management device 2 predicts the consumption power of the terminal device 3, and decides whether or not the operation of the terminal device 3 is allowed. When the operation of the terminal device 3 is allowed, the processing unit 30 is controlled to turn on the switching unit 38 so as to supply power from the power receiving unit 31 to the load power unit 37. When the operation of the terminal device 3 is not allowed, the processing unit 30 is controlled to keep the switching unit 38 turned off so as not to supply power from the power receiving unit 31 to the load power unit 37. With this operation, it is possible to limit power supply in order to prevent shortage of power supplied from the management device 2 to the terminal device 3.

In the following embodiment, the transmission line 1 is defined as a line constituted by two wires, and a constant DC voltage is applied between the wires of the transmission line 1. Further, the communication signal is defined as a high frequency signal obtained by modulating a carrier wave in a range of 100 to 300 kHz with a digital signal. As mentioned in the above, it is assumed that the communication signal constituted by a high frequency signal is transmitted by being superimposed on the DC voltage applied to the transmission line 1.

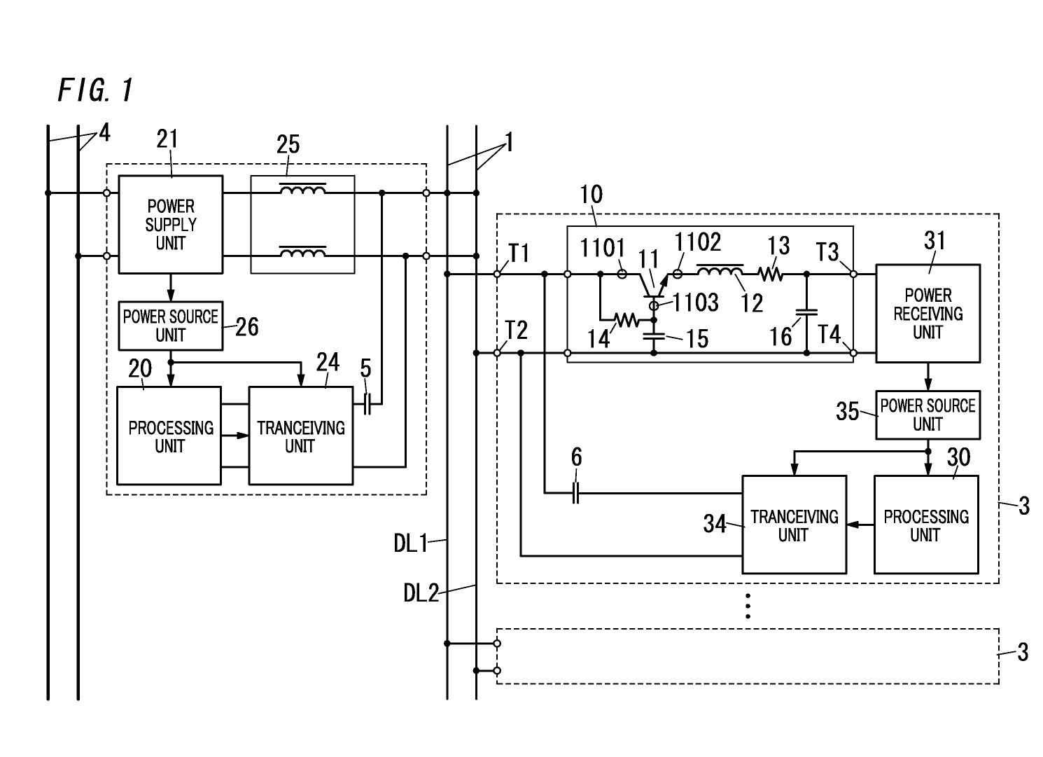

Further, with regard to the terminal device 3, used as the high impedance circuit 36 used for separating the DC power supplied from the power supply unit 21 and the communication signal transmitted between the transmitting unit 22 and the receiving unit 23 from each other is an electric choke circuit 10 (see FIG. 1). The electric choke circuit 10 includes an input terminal including two terminals and an output terminal including two terminals. The input terminal is interposed between the wires of the transmission line 1, and the output terminal is connected to the terminal device 3.

The electric choke circuit 10 is required to have a slight loss in DC power and have relatively high impedance to the communication signal. Further, it is necessary to configure the electric choke circuit 10 to, even if a load fluctuation in a load including the power receiving unit 31 occurs, suppress bad effect of the load fluctuation on the communication signal. In brief, it is necessary to suppress a change in the input impedance of the electric choke circuit 10 caused by the load fluctuation.

Moreover, it is necessary to prevent oscillation of the electric choke circuit 10 which occurs when the electric choke circuit 10 has negative resistance. In order to prevent the electric choke circuit 10 from having negative resistance, it is required that a phase angle (hereinafter simply referred to as “phase”) between two terminals constituting the input terminal of the electric choke circuit 10 is kept less than 90 degree. It is necessary to satisfy conditions required with regard to variations of the input impedance and the phase within at least a frequency band of a communication signal.

In the following embodiments, explanations are made to configurations of the electric choke circuit 10 fulfilling these conditions. In brief, the following explanations are made to the electric choke circuits 10 respectively configured to keep the input impedance at relatively high impedance, and suppress a change in the input impedance, and keep the phase less than 90 degree, within the frequency band of the communication signal.

### First Embodiment

As shown in FIG. 1, the present embodiment is explained based on an instance where the management device 2 and a plurality of the terminal devices 3 are connected to the transmission line 1. Basically, the present embodiment and the instance illustrated in FIG. 9 include the common configuration.

The management device 2 includes the power supply unit 21 and further includes a tranceiving unit 24 defined as an integration unit of the transmitting unit 22 and the receiving unit 23. The tranceiving unit 24 has a function of converting communication data provided from the processing unit 20 into a communication signal, and a function of converting a communication signal received via the transmission line 1 into communication data and then supplying the same to the processing unit 20. Interposed between the tranceiving unit 24 and the transmission line 1 is a capacitor 5 in order to block a DC component.

The power supply unit 21 is connected to lamp lines 4 receiving electric power from a commercial power source, for example. The power supply unit 21 is configured to output a DC constant voltage. The power supply unit 21 has output terminals connected to the transmission line 1 via the high impedance circuit 25 having sufficiently high impedance to a frequency (a frequency of the carrier wave in the present embodiment) of a communication signal. Further, the function of the connection limitation information generating unit 29 of the management device 2 as shown in FIG. 9 is implemented by a processing unit 20. The processing unit 20 includes an arithmetic processing device such as a microcomputer.

The terminal device 3 includes the power receiving unit 31 and a tranceiving unit 34. The power receiving unit 31 is configured to receive electric power from the transmission line 1 via the electric choke circuit 10. The tranceiving unit 34 is configured to act as the transmitting unit 32 and the receiving unit 33. The tranceiving unit 34 has a function of converting communication data provided from the processing unit 30 into a communication signal, and a function of converting a communication signal received via the transmission line 1 into communication data and then supplying the same to the processing unit 30. Interposed between the tranceiving unit 34 and the transmission line 1 is a capacitor 6 in order to block a DC component.

The power receiving unit 31 is configured to receive DC power from the transmission line 1 through the electric choke circuit 10 and then output a DC constant voltage. The terminal device 3 illustrated in FIG. 9 includes the switching unit 38 configured to control power supplied to the load power unit 37 to turn on and off the load power unit 37. However, the present embodiment gives no limitation to the processing unit 30. Thus, the load power unit 37 and the switching unit 38 are omitted. Besides, the processing unit 30 includes an arithmetic processing device such as a microcomputer.

The electric choke circuit 10 includes a variable impedance element configured to control impedance between the transmission line 1 and the power receiving unit 31. The variable impedance element 11 has a function of varying impedance between two connection terminals 1101 and 1102 in accordance with a voltage applied to a control terminal 1103 separated from the connection terminals 1101 and 1102. Accordingly, the variable impedance element 11 has three terminals or four terminals. Further, adopted as the variable impedance element 11 is an element configured to increase the impedance between the connection terminals 1101 and 1102 with a decrease in the voltage applied to the control terminal 1103 and to decrease the impedance between the connection terminals 1101 and 1102 with an increase in the voltage applied to the control terminal 1103.

In the illustrated instance, adopted as the variable impedance element 11 is an npn bipolar transistor. The bipolar transistor has a collector and an emitter used as the respective connection terminals 1101 and 1102, and has a base used as the control terminal 1103. Within an active region, an increase in the voltage applied to the base causes a decrease in the impedance between the collector and the emitter. Within a saturation region, the impedance between the collector and the emitter is kept at an approximately-constant small value. Besides, it is possible to use an active element (e.g., a MOSFET and an IGBT) as the variable impedance element 11.

The variable impedance element 11 has a first end (the collector in the illustrated instance) connected to a high voltage side line (hereinafter referred to as “positive-polarity line”) DL1 of the two lines constituting the transmission line 1. Further, the variable impedance element 11 has a second end (the emitter in the illustrated instance) connected to one of input terminals of the power receiving unit 31 via an inductor 12, for example. The other of the input terminals of the power receiving unit 31 is connected to a low voltage side line (hereinafter referred to as “negative-polarity line”) DL2 of the two lines constituting the transmission line 1.

With regard to the electric choke circuit 10, interposed between a first terminal T1 and a second terminal T2 respectively connected to the positive-polarity line DL1 and the negative-polarity line DL2 is a series circuit of a first resistor 14 and a first capacitor 15. The first resistor 14 has an end connected to the first terminal T1, and the first capacitor 15 has an end connected to the second terminal T2. Connected to the control terminal 1103 (the base in the illustrated instance) of the variable impedance element 11 is a connection point of the first resistor 14 and the first capacitor 15. Therefore, the impedance of the variable impedance element 11 is varied with a voltage across the first capacitor 15 (i.e., a potential at the connection point of the first resistor 14 and the first capacitor 15).

With regard to the electric choke circuit 10, interposed between a third terminal T3 and a fourth terminal T4 constituting an output terminal adapted in use to be connected to the power receiving unit 31 is a second capacitor 16. In other words, interposed between the first terminal T1 and the second terminal T2 constituting an input terminal of the electric choke circuit 10 is a series circuit of the variable impedance element 11, the inductor 12, a second resistor 13, and the second capacitor 16. Hence, electrical power is supplied to the power receiving unit 31 by way of the opposite ends of the second capacitor 16.

The following explanation is made to an operation of the electric choke circuit 10. When a communication signal is inputted into the first terminal T1 and the second terminal T2, a high frequency signal defining a communication signal passes through the series circuit of the first resistor 14 and the first capacitor 15. Thus, the variable impedance element 11 has relatively high impedance to a communication signal. Meanwhile, when a DC voltage is applied between the first terminal T1 and the second terminal T2, a voltage is developed across opposite ends of the first capacitor 15. Thus, the variable impedance element 11 has relatively low impedance to DC power.

Further, the inductor 12 is interposed between the first terminal T1 and the second terminal T2, and the second capacitor 16 is interposed between the third terminal T3 and the fourth terminal T4. Therefore, the electric choke circuit 10 allows passage of DC power but inhibits passage of a high frequency component constituting a communication signal. The inductor 12 and the second capacitor 16 constitute a resonance circuit. Consequently, it is considered that the electric choke circuit 10 shows great changes in the input impedance and the phase near a certain frequency.

As mentioned in the above, it is required that the input impedance becomes high impedance to a communication signal. It is preferred that the electric choke circuit 10 suppress a change in the load impedance of the electric choke circuit 10. In brief, the electric choke circuit 10 is configured such that a change in power supplied to an internal circuit of the terminal device 3 from the power receiving unit 31 acting as a load connected to the electric choke circuit 10 does not cause an effect on the input impedance of the electric choke circuit 10. In the electric choke circuit 10 illustrated, such a function is implemented by provision of the inductor 12, the first resistor 14, the first capacitor 15, and the second capacitor 16.

Meanwhile, serial connection of the second resistor 13 to the inductor 12 suppresses a change in the phase of the electric choke circuit 10. Hence, when the second resistor 13 is not provided, the inductor 12 and the second capacitor 16 are likely to cause strong resonance. In some cases, the above phase may exceed 90 degree near a resonance point. In contrast, the provision of the second resistor 13 can suppress the resonance and keep the above phase less than 90 degree even near the resonance point. In brief, with interposing the second resistor 13 between the input terminal and the output terminal, it is possible to prevent the electric choke circuit 10 from having negative resistance at a certain frequency. Hence, oscillation of the electric choke circuit 10 can be suppressed.

As apparent from the above, it is sufficient that the second resistor 13 has relatively high resistance so that the phase is kept less than 90 degree near the resonance point of the resonance circuit constituted by the inductor 12 and the second capacitor 16. In other words, the second resistor 13 is connected in series with the inductor 12. Further, the second resistor 13 has resistance selected such that the phase between the first terminal T1 and the second terminal T2 is kept less than 90 degree near the resonance point of the resonance circuit constituted by the inductor 12 and the second capacitor 16.

However, the second resistor 13 is inserted into a supply line of DC power from the transmission line 1 to the power receiving unit 31. Hence, a loss is increased with an increase in the resistance of the second resistor 13, and it is difficult to increase power supplied to the power receiving unit 31. Therefore, it is necessary to select inductance of the inductor 12 and capacitance of the second capacitor 16 in accordance with a frequency of a communication signal, and further it is necessary to select the resistance of the second resistor 13 in accordance with a magnitude of DC power supplied to the power receiving unit 31 and the phase. In brief, preferably, the resistance of the second resistor 13 is identical to the minimum resistance of a resistance range in which the phase is kept less than 90 degree.

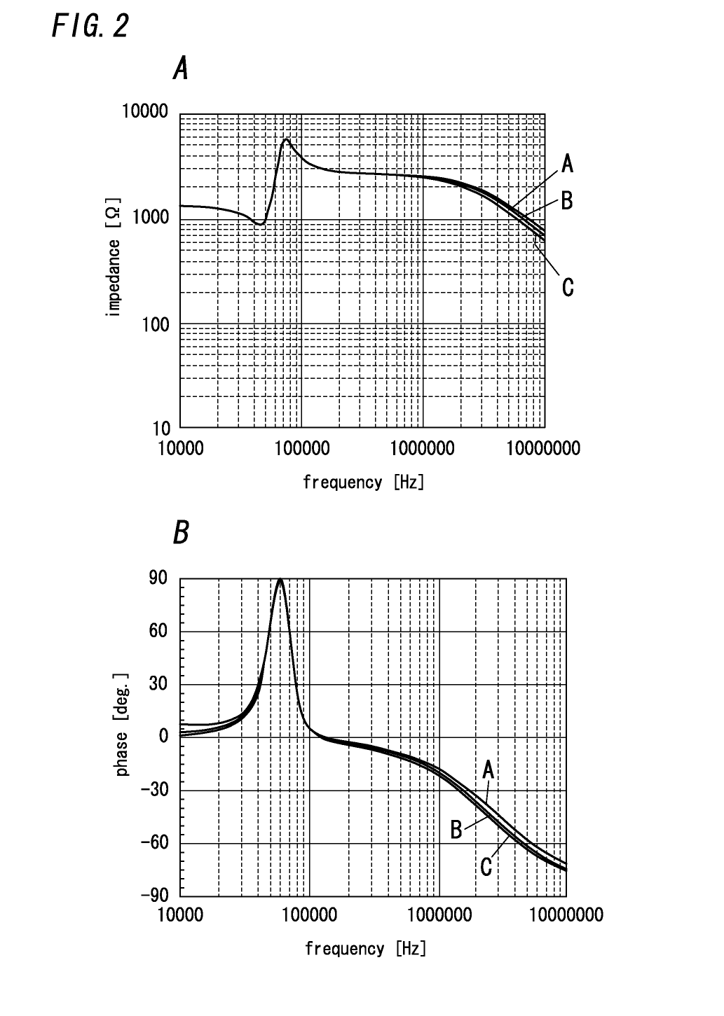

FIG. 2 shows a characteristic diagram obtained by use of a circuit simulator, wherein the inductor 12 has inductance of 100 μH, the second resistor 13 has the resistance of 10Ω, the first resistor 14 has the resistance of 2.7 kΩ, and the first capacitor 15 and the second capacitor 16 have the same capacitance of 0.1 μF. FIG. 2A shows frequency characteristics of the impedance of the electric choke circuit 10. FIG. 2B shows frequency characteristics of the phase. Further, in FIG. 2, a characteristic curve “A” is corresponding to an instance where a load (DC load) of the electric choke circuit 10 has the resistance of 500Ω, and a characteristic curve “B” is corresponding to an instance where the load (DC load) of the electric choke circuit 10 has the resistance of 1 kΩ, and a characteristic curve “C” is corresponding to an instance where the load (DC load) of the electric choke circuit 10 has the resistance of 2 kΩ.

According to the above condition, the resonance frequency of a combination of the inductor 12 and the second capacitor 16 is about 50 kHz. As apparent from FIG. 2, the impedance and the phase greatly change near the resonance frequency. Moreover, FIG. 2 indicates that a change in the resistance of the load does not cause great changes in the impedance and the phase. Further, FIG. 2 shows that the phase is kept less than 90 degree in an entire frequency band and then the electric choke circuit 10 does not act as a negative resistance and the oscillation can be suppressed.

The simulation result confirms that a change in the resistance of the load does not cause a variation of the impedance characteristic within a frequency band including at least a communication frequency (100 to 300 kHz). In other words, it is confirmed that the load variation causes no effect on the communication signal within the above frequency band and a communication performance can be stabilized. Further, within a wide frequency band, the electric choke circuit 10 does not have negative resistance. Consequently, the above result confirms that an unstable operation (e.g., oscillation) does not occur even when a change in a voltage between the lines resulting from the load variation and a frequency of a constantly-existing noise exists.

As mentioned in the above, the communication system includes the terminal device 3, the power supply unit 21, and the tranceiving unit 24. The power supply unit 21 and the tranceiving unit 24 are connected to the terminal device 3 via the transmission line 1. The power supply unit 21 is configured to supply power to the terminal device 3 via the transmission line 1 by applying a DC voltage to the transmission line 1. The tranceiving unit 24 is configured to transmit a communication signal to the terminal device 3 via the transmission line 1 by superimposing the communication signal onto the DC voltage applied to the transmission line 1. The communication signal is generated by modulating a carrier wave, and has the same frequency as the carrier wave.

The terminal device 3 includes the electric choke circuit 10, the power receiving unit 31, and the tranceiving unit 34. The electric choke circuit 10 is connected to the transmission line 1. The electric choke circuit 10 is configured to separate, from each other, the DC voltage and the communication signal provided to the transmission line 1, and supply the separated DC voltage to the power receiving unit 31, and send the separated communication signal to the tranceiving unit 34. Further, the electric choke circuit 10 includes the input terminal, the output terminal, the variable impedance element 11, the inductor 12, the first resistor 14, the first capacitor 15, the second capacitor 16, and the second resistor 13.

The input terminal is connected to the transmission line 1. The input terminal includes the first terminal T1 and the second terminal T2. The output terminal is connected to the power receiving unit 31. The output terminal includes the third terminal T3 electrically connected to the first terminal T1, and the fourth terminal T4 electrically connected to the second terminal T2.

The variable impedance element 11 includes the first connection terminal 1101, the second connection terminal 1102, and the control terminal 1103. The variable impedance element 11 is configured to vary the impedance between the first connection terminal 1101 and the second connection terminal 1102 in accordance with a voltage applied to the control terminal 1103. The first connection terminal 1101 is connected to the first terminal T1. The second connection terminal 1102 is connected to the third terminal T3.

The inductor 12 is interposed between the second connection terminal 1102 of the variable impedance element 11 and the third terminal T3. The first resistor 14 is interposed between the first terminal T1 and the control terminal 1103. The first capacitor 15 is interposed between the control terminal 1103 and the second terminal T2.

In brief, the first capacitor 15 and the first resistor 14 are interposed between the first terminal T1 and the second terminal T2, and constitute a series circuit configured to apply a terminal voltage of the first capacitor 15 to the control terminal 1103 of the variable impedance element 11.

The second capacitor 16 is interposed between the third terminal T3 and the fourth terminal T4. The second resistor 13 is interposed between the second connection terminal 1102 of the variable impedance element 11 and the third terminal T3. The second resistor 13 is configured to suppress a phenomenon that resistance characteristics of a circuit between the input terminal and the output terminal have a negative resistance region within the frequency band including at least the frequency (communication signal) of the communication signal.

Besides, actually, the inductor 12 is made of an electric wire. Therefore, the inductor 12 has DC resistance (internal resistance). The second resistor 13 has relatively small resistance. Hence, with appropriately selecting a diameter and the number of windings of the inductor 12, it is possible to omit a DC resistor corresponding to the second resistor 13. In other words, with appropriately selecting a configuration condition of the inductor 12, it is possible to design the electric choke circuit 10 capable of keeping the phase less than 90 degree without providing the inductor 12 as a concrete entity (without adding the second resistor 13 as a separate part).

In the present embodiment, the first terminal T1 is designed as a terminal connected to the positive-polarity line DL1. However, the first terminal T1 may be designed as a terminal connected to the negative-polarity line DL2. Such modification can be applied to the following embodiments.

### Second Embodiment

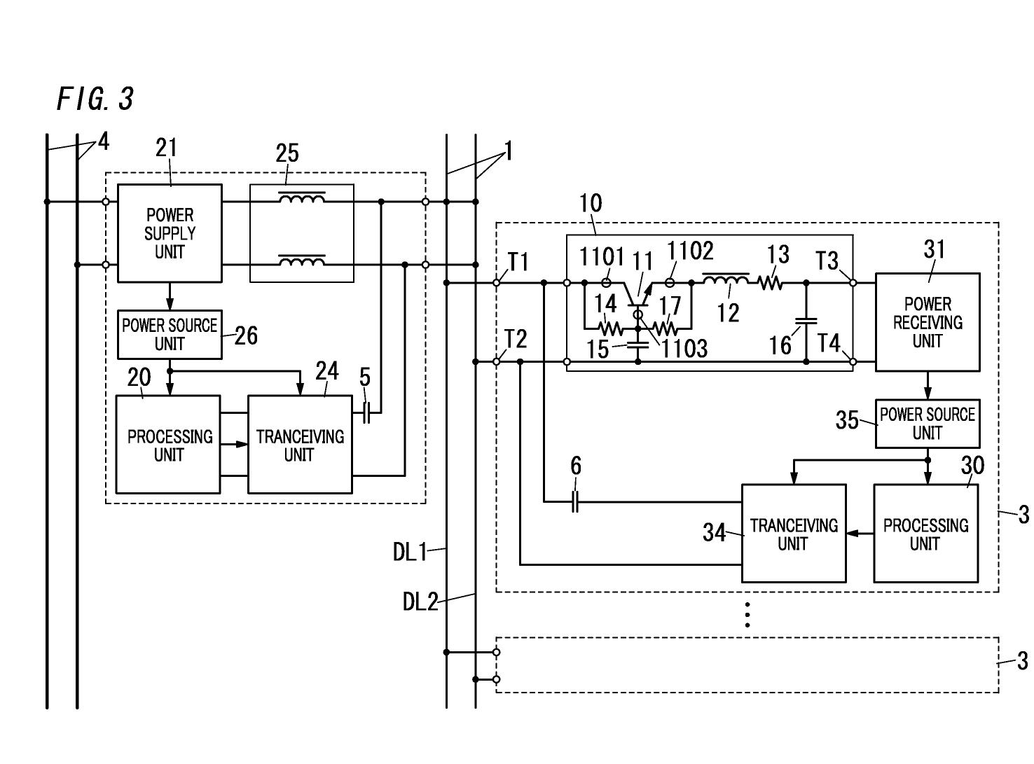

As shown in FIG. 3, in the present embodiment, with regard to the variable impedance element 11 of the electric choke circuit 10, interposed between one connection terminal (the emitter) and the control terminal 1103 (the base) is a third resistor 17 for bias. In brief, the electric choke circuit 10 includes the third resistor 17. The third resistor 17 is interposed between the control terminal 1103 and the second connection terminal 1102. The other configuration of the present embodiment is similar to the first embodiment.

So long as the communication signal superimposed on the DC voltage has relatively small amplitude, a configuration devoid of the third resistor 17 (e.g., the configuration mentioned in the first embodiment) is available. However, when the communication signal has relatively large amplitude, a base voltage of a transistor used as the variable impedance element 11 is likely to fall below an emitter voltage thereof. In this case, the transistor may operate within a cutoff region. Hence, a problem that an input voltage to the power receiving unit 31 is decreased may arise.

According to the configuration of the present embodiment, applied to the base of the transistor is a voltage divided based on a resistance ratio of the first resistor 14 and the third resistor 17 from a voltage between the collector and the emitter of the transistor. Hence, it is possible to prevent the base voltage from falling below the emitter voltage. In brief, even if the amplitude of the communication signal is greatly changed, the variation of the impedance is suppressed. Accordingly, it is possible to stabilize the communication performance.

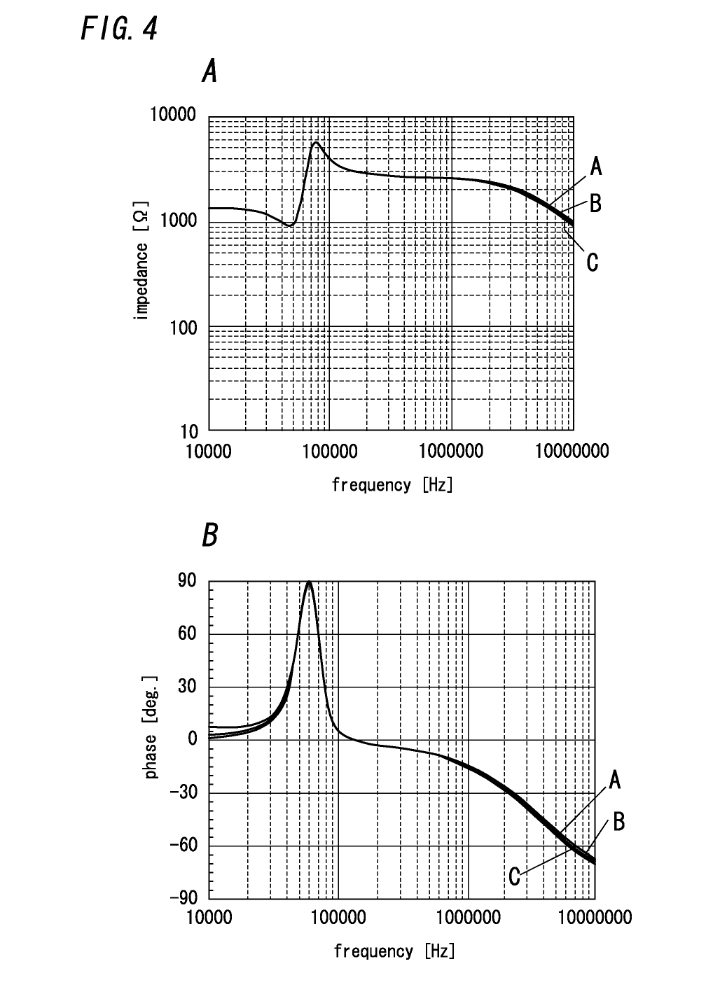

FIG. 4 shows a characteristic diagram obtained by use of a circuit simulator, wherein the inductor 12 has inductance of 100 pH, the second resistor 13 has the resistance of 10Ω, the first resistor 14 has the resistance of 2.7 kΩ, the first capacitor 15 and the second capacitor 16 have the same capacitance of 0.1 μF, and the third resistor 17 has the resistance of 1.3 kΩ. FIG. 4A shows frequency characteristics of the impedance of the electric choke circuit 10. FIG. 4B shows frequency characteristics of the phase. Further, in FIG. 4, a characteristic curve “A” is corresponding to an instance where the load (DC load) of the electric choke circuit 10 has the resistance of 500Ω, and a characteristic curve “B” is corresponding to an instance where the load (DC load) of the electric choke circuit 10 has the resistance of 1 kΩ, and a characteristic curve “C” is corresponding to an instance where the load (DC load) of the electric choke circuit 10 has the resistance of 2 kΩ.

The above condition is the same as the condition used in the simulation by use of the circuit simulator in the first embodiment except the provision of the third resistor 17. The same advantage as the first embodiment can be obtained. In addition, it is possible to adjust the bias of the transistor used as the variable impedance element 11 without deteriorating the impedance. It is therefore possible to appropriately select an operation point of the transistor in accordance with the amplitude of the communication signal inputted into the electric choke circuit 10.

### Third Embodiment

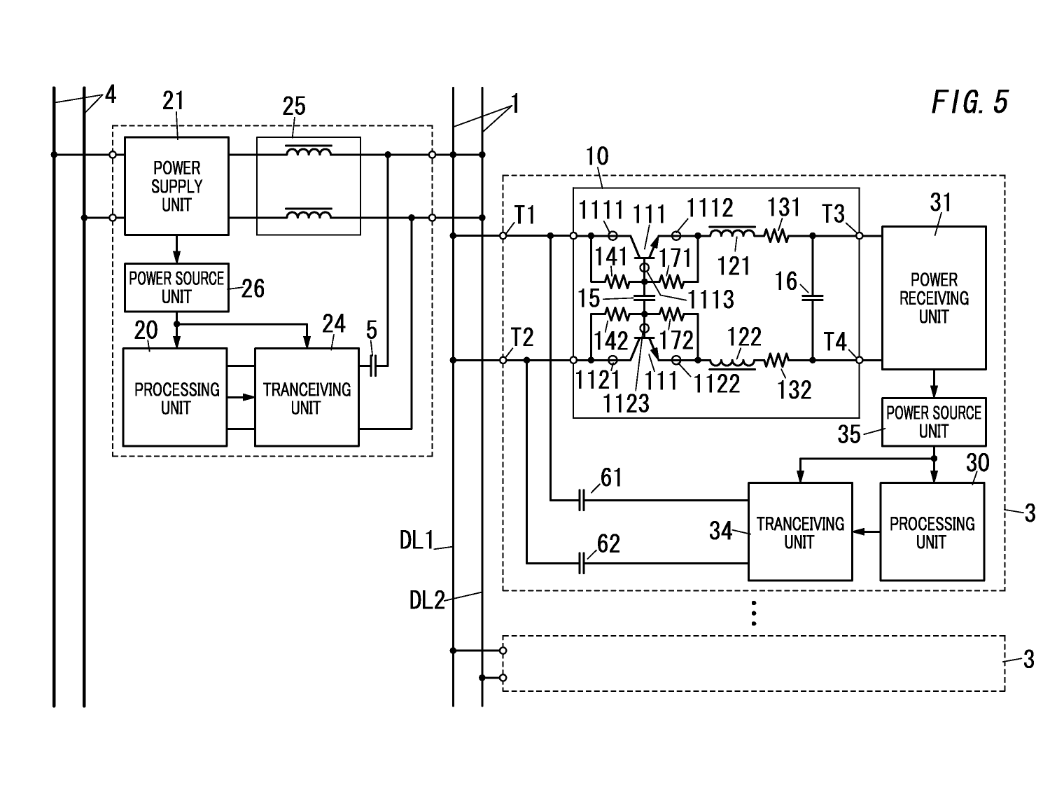

As shown in FIG. 5, the present embodiment has a configuration in which the electric choke circuit 10 is designed to be a balance-type electronic choke circuit. In brief, according to the configurations mentioned in the first and second embodiments, the single variable impedance element 11 is provided, and the fourth terminal T4 is directly connected to the second terminal T2 connected to the negative-polarity line DL2. In contrast, in the present embodiment, an additional variable impedance element is interposed between the second terminal T2 and the fourth terminal T4. Hence, the present embodiment includes two variable impedance elements 111 and 112, and the positive-polarity side and the negative-polarity side with regard to the electric choke circuit have the same configuration. In the present configuration, a capacitor 61 is interposed between the tranceiving unit 34 and the positive-polarity line DL1, and a capacitor 62 is interposed between the tranceiving unit 34 and the negative-polarity line DL2.

The configuration instance shown in FIG. 5 is obtained by modifying the second embodiment such that the electric choke circuit is a balance-type electronic choke circuit. Hence, there are sets of two necessary components respectively interposed between the first terminal T1 and the third terminal T3 and between the second terminal T2 and the fourth terminal T4, that is, a set of the two variable impedance elements 111 and 112, a set of two inductors 121 and 122, a set of two second resistors 131 and 132, a set of two first resistors 141 and 142, and a set of two third resistors 171 and 172.

In brief, the variable impedance element 111 has a connection terminal 1111 (a collector in the illustrated instance) connected to the first terminal T1, and the variable impedance element 112 has a connection terminal 1121 (a collector in the illustrated instance) connected to the second terminal T2. In addition, the second resistor 131 is connected in series with the inductor 121, and the second resistor 132 is connected in series with the inductor 122. Further, the second resistors 131 and 132 have resistance selected such that the phase between the first terminal T1 and the second terminal T2 is kept less than 90 degree near the resonance point of the resonance circuit constituted by the inductors 121 and 122 and the second capacitor 16.

Additionally, components interposed between the positive-polarity side and the negative-polarity side, that is, the first capacitor 15 and the second capacitor 16 are shared. The first capacitor 15 is connected between the bases of the two transistors respectively defining the variable impedance elements 111 and 112, and the second capacitor 16 is interposed between the third terminal T3 and the fourth terminal T4 constituting the output terminal. The transistors are used as the variable impedance elements 111 and 112. Thus, the transistor between the first terminal T1 and the third terminal T3 is an npn transistor, and the transistor between the second terminal T2 and the fourth terminal T4 is a pnp transistor.

The electric choke circuit 10 includes the input terminal, the output terminal, the variable impedance elements 111 and 112, the inductors 121 and 122, the first resistors 141 and 142, the first capacitor 15, the second capacitor 16, and the second resistors 131 and 132.

The input terminal is connected to the transmission line 1. The input terminal includes the first terminal T1 and the second terminal T2. The output terminal is connected to the power receiving unit 31. The output terminal includes the third terminal T3 electrically connected to the first terminal T1, and the fourth terminal T4 electrically connected to the second terminal T2.

The variable impedance element 111 includes the first connection terminal 1111, the second connection terminal 1112, and the control terminal 1113. The variable impedance element 111 is configured to vary the impedance between the first connection terminal 1111 and the second connection terminal 1112 in accordance with a voltage applied to the control terminal 1113. The first connection terminal 1111 is connected to the first terminal T1. The second connection terminal 1112 is connected to the third terminal T3.

The variable impedance element 112 includes the first connection terminal 1121, the second connection terminal 1122, and the control terminal 1123. The variable impedance element 112 is configured to vary the impedance between the first connection terminal 1121 and the second connection terminal 1122 in accordance with a voltage applied to the control terminal 1123. The first connection terminal 1121 is connected to the second terminal T2. The second connection terminal 1122 is connected to the fourth terminal T4.

The inductor 121 is interposed between the second connection terminal 1112 of the variable impedance element 111 and the third terminal T3. The inductor 122 is interposed between the second connection terminal 1122 of the variable impedance element 112 and the fourth terminal T4.

The first resistor 141 is interposed between the first terminal T1 and the control terminal 1113. The first resistor 142 is interposed between the second terminal T2 and the control terminal 1123. The first capacitor 15 is interposed between the control terminal 1113 of the variable impedance element 111 and the control terminal 1123 of the variable impedance element 112.

The second capacitor 16 is interposed between the third terminal T3 and the fourth terminal T4. The second resistor 131 is interposed between the second connection terminal 1112 of the variable impedance element 111 and the third terminal T3. The second resistor 132 is interposed between the second connection terminal 1122 of the variable impedance element 112 and the fourth terminal T4.

The second resistors 131 and 132 are configured to suppress a phenomenon that resistance characteristics of a circuit between the input terminal and the output terminal have a negative resistance region within the frequency band including at least the frequency of the communication signal.

With adopting the configuration illustrated in FIG. 5 as the electric choke circuit 10, the tranceiving unit 34 (and the tranceiving unit 24) can be designed as a balanced circuit, and the transmission line 1 can be designed as a balanced line. As a result, common-mode noise can be reduced. In other words, resistance to external noise can be improved.

The present embodiment shows the instance where the configuration of the second embodiment is modified as a balanced circuit. However, the configuration of the first embodiment can be modified as a balanced circuit. Further, a configuration of the following fourth embodiment can be modified as a balanced circuit. The other configuration and the other operation of the present embodiment are similar to the first and second embodiments.

### Fourth Embodiment

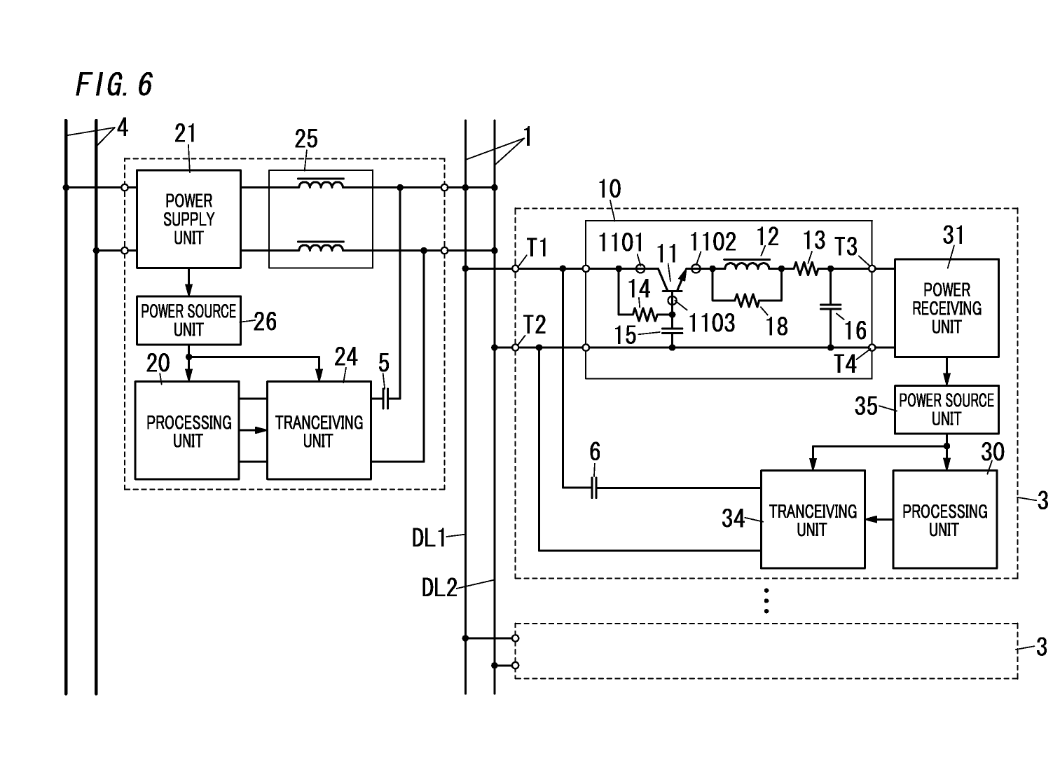

According to the configurations explained in the first to third embodiments, in order to prevent the electric choke circuit 10 from having negative resistance, the second resistor 13 is connected in series with the inductor 12. In contrast, as shown in FIG. 6, the present embodiment shows an instance where a second resistor 18 is connected in parallel with the inductor 12. It is known that the second resistor 18 connected in parallel with the inductor 12 decreases a resonance quality factor “Q” of the resonance circuit constituted by the inductor 12 and the second capacitor 16. The second resistor 18 acts as a Q-damping resistor. With decreasing the resistance of the second resistor 18, it is possible to narrow a variation range of the phase with regard to a frequency.

As mentioned in the above, the second resistor 18 is connected in parallel with the inductor 12. The resistance of the second resistor 18 is selected such that the internal resistance of the inductor 12 is considered to be substantially negligible.

With regard to the present embodiment, the frequency characteristics of the impedance and the phase were obtained by use of a circuit simulator in a similar manner as the other embodiments. The condition used in this simulation is as follows. That is, the inductor 12 has inductance of 100 μH, the first resistor 14 has the resistance of 2.7 kΩ, the first capacitor 15 and the second capacitor 16 have the same capacitance of 0.1 μF, and the second resistor 18 has the resistance of 50Ω. In other words, the above simulation was performed under the condition same as the second embodiment except the second resistor 18 is connected instead of the second resistor 13 of the second embodiment.

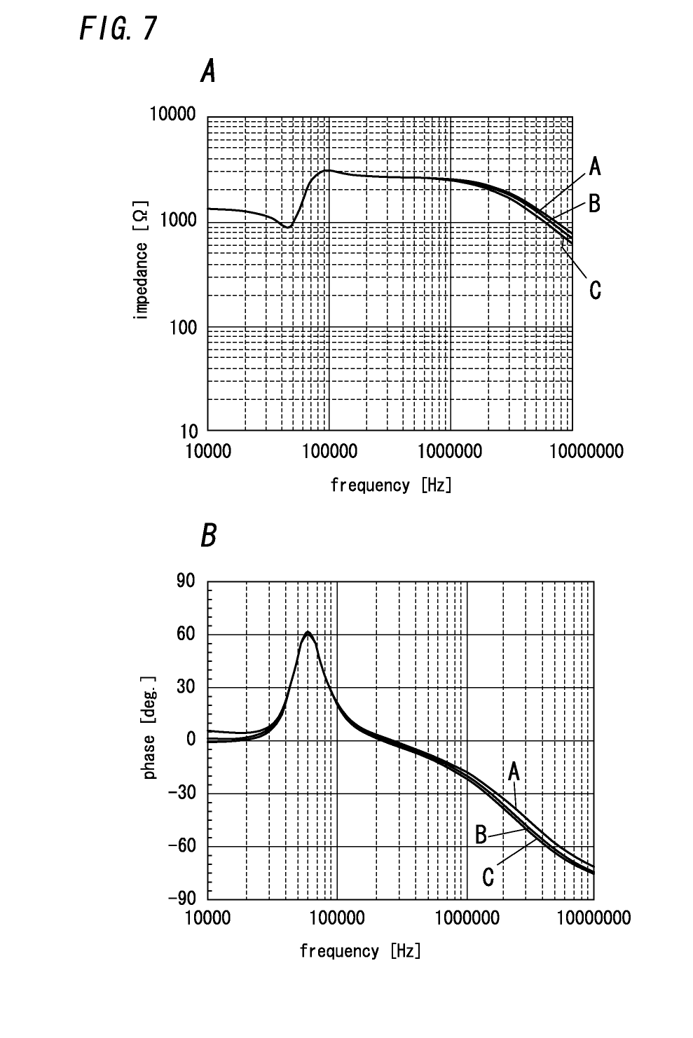

FIG. 7 shows a characteristic diagram obtained by use of a circuit simulator. Similar to the first and second embodiments, FIG. 7A shows frequency characteristics of the impedance of the electric choke circuit 10, and FIG. 7B shows frequency characteristics of the phase. Further, in FIG. 7, a characteristic curve “A” is corresponding to an instance where a load (DC load) of the electric choke circuit 10 has the resistance of 500Ω, and a characteristic curve “B” is corresponding to an instance where the load (DC load) of the electric choke circuit 10 has the resistance of 1 kΩ, and a characteristic curve “C” is corresponding to an instance where the load (DC load) of the electric choke circuit 10 has the resistance of 2 kΩ.

According to the configuration of the present embodiment, the second resistor 18 is connected in parallel with the inductor 12. When the inductor 12 is designed such that the internal resistance of the inductor 12 is substantially negligible compared to the resistance of the second resistor 18, a DC current flows through the inductor 12. Thus, it is possible to suppress an electrical power loss. As a result, it is possible to supply more DC power than the second embodiment to the power receiving unit 31.

The present embodiment illustrates the instance where the second resistor 18 is employed as an alternative to the second resistor 13 in the configuration of the second embodiment. It is possible to adopt the second resistor 18 as an alternative to the second resistor 13 in the configuration of the first embodiment. The other configuration and the other operation of the present embodiment are similar to the first and second embodiments.

Besides, in the above configuration, the power supply unit 21 provided to the management device 2 supplies DC power to the terminal device 3 via the transmission line 1. However, the power supply unit 21 can be separated from the management device 2.

The transmission line 1 is not limited to a two wire transmission line, but may be a transmission line including three or more wires which includes a single common wire and a plurality of voltage wires having different electric potentials with reference to the electric potential of the common wire. Alternatively, it is possible to use a plurality of the transmission lines having different voltages across their respective paired wires.

Moreover, the aforementioned frequency of the communication signal is merely an example, and is not limited to the above. A baseband signal can be used as an alternative to the communication signal generated by modulating the carrier wave. For example, basically, a voltage mode communication signal of a voltage corresponding to a signal value is used as the baseband signal. Alternatively, a current mode communication signal of a current corresponding to a signal value also can be used as the baseband signal.

The above explanations are made to preferable embodiments of the present invention. These embodiments can be revised and modified variously by the person skilled in the art without departing from the underlying spirit and the scope (i.e., claims) of the present invention.

1. A communication system comprising:
a management device and a terminal device designed to communicate with each other via a transmission line; and
a power supply unit configured to supply electric power to said terminal device via the transmission line,
wherein said terminal device comprises:
an electronic choke circuit configured to separate the electric power supplied from said power supply unit and a communication signal from each other; and
a power receiving unit configured to receive the electric power separated from the communication signal by said electronic choke circuit, and
said electronic choke circuit comprises:
a first terminal and a second terminal constituting an input terminal adapted in use to be connected the transmission line;
a third terminal and a fourth terminal constituting an output terminal adapted in use to be connected said power receiving unit;
a variable impedance element placed in at least one of a position between said first terminal and said third terminal and a position between said second terminal and said fourth terminal, said variable impedance element being configured to vary its impedance in accordance with a voltage applied to a control terminal;
an inductor interposed between said variable impedance element and said output terminal;
a first capacitor connected between said first terminal and said second terminal via a first resistor so as to apply its terminal voltage to said control terminal of said variable impedance element;
a second capacitor interposed between said third terminal and said fourth terminal; and
a second resistor connected between said variable impedance element and said output terminal, said second resistor configured to suppress a phenomenon that resistance characteristics of a circuit between said input terminal and said output terminal have a negative resistance region within a frequency band including at least a frequency of the communication signal.

2. A communication system as set forth in claim 1, wherein
said electronic choke circuit further comprises a third resistor connected in series with said first resistor, and
connected in parallel with said variable impedance element is a series circuit of said first resistor and said third resistor.

3. A communication system as set forth in claim 1, wherein
said electronic choke circuit is designed as a balanced circuit.

4. A communication system as set forth in claim 1, wherein
said communication system comprising a plurality of said terminal devices connected to the transmission line.

5. An electronic choke circuit comprising:
a first terminal and a second terminal constituting an input terminal;
a third terminal and a fourth terminal constituting an output terminal;
a variable impedance element placed in at least one of a position between said first terminal and said third terminal and a position between said second terminal and said fourth terminal, said variable impedance element being configured to vary its impedance in accordance with a voltage applied to a control terminal;
an inductor interposed between said variable impedance element and said output terminal;
a first capacitor connected between said first terminal and said second terminal via a first resistor so as to apply its terminal voltage to said control terminal of said variable impedance element;
a second capacitor interposed between said third terminal and said fourth terminal; and
a second resistor connected between said variable impedance element and said output terminal, said second resistor configured to suppress a phenomenon that resistance characteristics of a circuit between said input terminal and said output terminal have a negative resistance region within a frequency band including at least a frequency of the communication signal.
